(19) United States
(12) Patent Application Publication
(10) Pub. No.: US 2012/0025213 A1
(43) Pub. Date: Feb. 2, 2012

(54) THIN FILM SEMICONDUCTOR SUBSTRATE AND APPARATUS FOR MANUFACTURING THE SAME

(76) Inventors: Shigeyoshi Otsuki, Tokyo (JP); Toshimasa Eguchi, Tokyo (JP); Masatoshi Naka, Tokyo (JP); Kazushige Takechi, Tokyo (JP); Kiyoshi Ouchi, Chiba (JP)

(21) Appl. No.: 12/737,543

(22) PCT Filed: Mar. 27, 2009
(86) PCT No.: PCT/JP2009/056283

§ 371 Date: Apr. 12, 2011

(30) Foreign Application Priority Data
Jul. 24, 2008 (JP) 2008191137

(51) Int. Cl. H01L 27/15; B32B 38/18

(52) U.S. Cl. 257/88; 156/379.7; 156/499; 257/E27.121

(57) ABSTRACT

A flat panel display is manufactured by mass production and easily stored and transported at low cost. Provided is a thin film semiconductor substrate which faces a plastic substrate 7 and is combined with the plastic substrate 7 so as to be a flat panel display. Single-board-like insulating substrates 4 each of which has a thin film semiconductor array 3 are continuously bonded onto a lengthy plastic film 2. An apparatus is also provided for manufacturing the thin film semiconductor substrate which faces the plastic substrate 7 and is combined with the plastic substrate 7 so as to be the flat panel display. The apparatus includes a bonding section 20 for continuously bonding, onto the lengthy plastic film 2, the single-board-like insulating substrates 4 each of which has a protection film 5 bonded thereon for protecting the thin film semiconductor array 3, a peeling section 30 for peeling the protection film 5 by heating or ultraviolet irradiation, a laminating section 40 which laminates a lengthy protection film 6 on the lengthy plastic film 2 so as to protect the thin film semiconductor array 3, and a take-up section 50 for taking up, in a roll-shape, the lengthy plastic film 2, which has the lengthy protection film 6 laminated thereon.

### FIELD OF THE INVENTION

The present invention relates to a thin film semiconductor substrate formed by continuously bonding single-board-like insulating substrates including a thin film semiconductor array onto a lengthy plastic film and an apparatus for manufacturing the same.

### DESCRIPTION OF THE RELATED ART

As a display apparatus of various electronics, there is a flat panel display. Generally, flat panel displays have features, such as thin, lightweight, low power consumption, and easiness of color display. From these features, flat panel displays are widely used as displays of personal computers and various mobile information terminals (Patent Document 1).

The flat panel displays include not only liquid crystal display panels, but also EL display panels which use TFT as pixel-switching elements, or the like. Among these flat panel displays, there is a flat panel display in which a thin film semiconductor substrate faces a plastic substrate and is combined with the plastic substrate. As the thin film semiconductor substrate, there is a thin film semiconductor substrate in which a thin film semiconductor array such as a TFT element (TFT: Thin Film Transistor), a contact sensor, a photoelectric conversion element, or the like is formed on an insulating substrate by using a thin film semiconductor technology (Patent Document 2).

For example, in order to form an active matrix driving liquid crystal display element as the thin film semiconductor array, a TFT element, an MIM element (Metal Insulator Metal), or the like needs to be formed on a substrate, and a glass substrate is mainly used as the substrate. However, a high temperature process is required to form a TFT element on a plastic substrate, so that mass production is difficult due to a problem of thermal expansion and thermal contraction of the substrate. Therefore, there is a thin film semiconductor substrate in which a plastic substrate is used as one side substrate, a glass substrate on which TFT elements are formed is used as the other side substrate, and both substrates are bonded together via a seal material (Patent Document 3).

Patent Document 1: Japanese Patent Application Laid-Open No. 2001-296817

Patent Document 2: Japanese Patent Application Laid-Open No. 2005-51208

Patent Document 3: Japanese Patent Application Laid-Open No. 2007-17655

In such a thin film semiconductor substrate, the thin film semiconductor array is formed on, for example, a single-board-like insulating substrate having a predetermined size, and the single-board-like insulating substrate including the thin film semiconductor array faces a plastic substrate and is combined with the plastic substrate to manufacture a flat panel display. In this case, for example, when storing or transporting the single-board-like insulating substrates, a box or a case for housing the single-board-like insulating substrates is needed for protecting from damage. Therefore, the time and labor to take the substrates in and out from a container and a space to store the substrates are required, and this is a cause to increase the cost.

In addition, to manufacture flat panel displays, the single-board-like insulating substrates need to be quickly placed one after another in a predetermined position on the plastic substrate. Therefore, a mechanism to place the single-board-like insulating substrate becomes high-precision and complex, so that mass production is difficult and the cost increases. Further, in the process to manufacture the flat panel display, the larger the sizes of the single-board-like insulating substrate and the plastic substrate are, the larger the dimensional difference caused due to a difference of thermal expansions and thermal contractions between the substrates caused by temperature change is, so that there is a risk that the flat panel display becomes defective. Furthermore, the larger the sizes of the substrates are, the larger the production equipment is, so that there are problems that the equipment investment increases and a large installation area is required.

The present invention is made in view of the above situation, and an object of the present invention is to provide a thin film semiconductor substrate that enables mass production of flat panel displays and is easily stored and transported at low cost, and apparatus for manufacturing the same.

### SUMMARY OF THE INVENTION

To solve the problems and achieve the object, the present invention is configured as described below.

The invention according to a first aspect is a thin film semiconductor substrate characterized in that the thin film semiconductor substrate faces a plastic substrate and is combined with the plastic substrate so as to be a flat panel display, and in the thin film semiconductor substrate, single-board-like insulating substrates each of which has a thin film semiconductor array are continuously bonded onto a lengthy plastic film.

The invention according to a second aspect is the thin film semiconductor substrate described in claim 1, and the thin film semiconductor substrate is characterized in that the insulating substrates are formed by laminating the lengthy protection film to the insulating substrates so that the insulating substrates are protected by the lengthy plastic film.

The invention according to a third aspect is the thin film semiconductor substrate according to the first or second aspect, and the thin film semiconductor substrate is characterized in that the lengthy plastic film is formed of the same material as that of the plastic substrate.

The invention according to a fourth aspect is the thin film semiconductor substrate according to any one of the first to third aspects, and the thin film semiconductor substrate is characterized in that the thickness of the thin film semiconductor array is 0.1 mm or less.

The invention according to a fifth aspect is the thin film semiconductor substrate according to any one of the first to fourth aspects, and the thin film semiconductor substrate is characterized in that the plastic substrate is a color filter.

The invention according to a sixth aspect is an apparatus for manufacturing a thin film semiconductor substrate which faces a plastic substrate and is combined with the plastic substrate so as to be the flat panel display, and the apparatus includes
a bonding section for continuously bonding, onto the lengthy plastic film, the single-board-like insulating substrates each of which has a protection film bonded thereon for protecting the thin film semiconductor array,
a peeling section for peeling the protection film by heating or ultraviolet irradiation,
a laminating section which laminates a lengthy protection film on the lengthy plastic film so as to protect the thin film semiconductor array, and
a take-up section for taking up, in a roll-shape, the lengthy plastic film, which has the lengthy protection film laminated thereon.

The invention according to a seventh aspect is the apparatus according to the sixth aspect for manufacturing a thin film semiconductor substrate, and the apparatus is characterized in that the lengthy plastic film is formed of the same material as that of the plastic substrate.

The invention according to an eighth aspect is the apparatus according to the sixth or seventh aspect for manufacturing a thin film semiconductor substrate, and the apparatus is characterized in that the thickness of the thin film semiconductor array is 0.1 mm or less.

According to the configuration described above, the present invention has effects as described below.

The invention according to the first aspect is a roll-shaped thin film semiconductor substrate including thin film semiconductor arrays. The roll-shaped thin film semiconductor substrate is faced to a plastic substrate and can be quickly combined with the plastic substrate at an accurate position so as to be a flat panel display. Thus, mass production of the flat panel display is possible. In addition, by using a roll-shaped thin film semiconductor substrate including thin film semiconductor arrays, it is easy to store and transport the thin film semiconductor substrate without needing a special storage container or storage space.

In the invention according to the second aspect, the insulating substrate is protected by the lengthy protection film, so that it is possible to prevent the roll-shaped thin film semiconductor substrate from being defective.

In the invention according to the third aspect, a single-board-like insulating substrate on which a thin film semiconductor array is formed in advance is used, so that it is possible to use a lengthy plastic film having an upper temperature limit lower than that of the manufacturing process of the semiconductor array, and it is possible to prevent a dimensional difference from occurring due to a difference of thermal expansions and a difference of thermal contractions caused by temperature change.

In the invention according to the fourth aspect, the thickness of the thin film semiconductor array is 0.1 mm or less, so that the thin film semiconductor substrate has a thin shape.

In the invention according to the fifth aspect, the plastic substrate is a color filter, so that a flat panel display capable of color displaying can be formed.

In the invention according to the sixth aspect, single-board-like insulating substrates on which a thin film semiconductor array is formed in advance are used, and the single-board-like insulating substrates are continuously bonded onto a lengthy plastic film, so that a thin film semiconductor substrate which can be taken up in a roll-shape can be manufactured at low cost.

In the invention according to the seventh aspect, since a single-board-like insulating substrate on which a thin film semiconductor array is formed in advance is used, it is possible to use a lengthy plastic film having an upper temperature limit lower than that of the manufacturing process of the semiconductor array, and also it is possible to obtain a thin film semiconductor substrate which can be taken up in a roll-shape by continuously bonding the single-board-like insulating substrates onto a lengthy plastic film.

In the invention according to the eighth aspect, the thickness of the thin film semiconductor array is 0.1 mm or less, so that it is possible to obtain a thin film semiconductor substrate having a thin shape.

### DETAILED DESCRIPTION OF THE EMBODIMENT

Hereinafter, an embodiment of the thin film semiconductor substrate of the present invention and the apparatus for manufacturing the thin film semiconductor substrate will be described. The embodiment of the present invention shows the best mode for carrying out the invention, and the present invention is not limited to this.

### [Thin Film Semiconductor Substrate]

FIG. 1 is a schematic configuration diagram of the thin film semiconductor substrate. The thin film semiconductor substrate according to the embodiment faces a plastic substrate and is combined with the plastic substrate so as to be a flat panel display, and is formed by continuously bonding single-board-like insulating substrates 4 each of which has a thin film semiconductor array 3 onto a lengthy plastic film 2. the insulating substrate 4 is formed by laminating a lengthy protection film 6 to the insulating substrate 4 so that the insulating substrate 4 is protected by the lengthy plastic film 2.

FIG. 2 is a diagram for explaining a manufacturing process of the thin film semiconductor substrate. In this embodiment, as shown in FIG. 2A, the single-board-like insulating substrates 4 including the thin film semiconductor array 3 are used to manufacture the thin film semiconductor substrate. The thin film semiconductor array 3 is protected by a protection film 5. As shown in FIG. 2B, the single-board-like insulating substrates 4 are continuously bonded onto the lengthy plastic film 2. Then, as shown in FIG. 2C, the protection films 5 are heated or irradiated by ultraviolet light, and the protection films 5 are peeled from the single-board-like insulating substrates 4. After the protection films 5 are peeled, as shown in FIG. 2D, the lengthy protection film 6 is laminated to the insulating substrates 4 so that the insulating substrates 4 are protected by the lengthy plastic film 2.

In this embodiment, a glass substrate etched to a thin plate is used for the single-board-like insulating substrate 4. For example, the thin film semiconductor array 3 is formed on an alkali-free glass substrate having a thickness of 0.7 mm by a normal low-temperature polysilicon technique, and further the glass substrate is etched to a thin substrate having a thickness smaller than 0.1 mm by a method described in Patent Document 1 or the like. As the thin film semiconductor array 3, for example, a TFT element, a contact sensor, a photoelectric conversion element, and the like are used.

Patent Document 4: Japanese Patent Application Laid-Open No. 2008-13389

A flexible resin base material is used for the lengthy plastic film 2. The lengthy protection film 6 and the protection film 5 are formed of a flexible resin base material and an adhesive material layer. For the flexible resin base material, for example, a polyester film, a polypropylene film, a polyethylene film, a polycarbonate film, a polystyrene film, a triacetylcellulose film, or the like can be used, and among these films, it is preferable to use a biaxially-drawn polyester film in which a smoother surface can be easily formed and which has a high productivity.

The thickness of the flexible resin base material is preferred to be 30 to 300 μm. If the thickness is smaller than 30 μm, there may be a problem, such as, the film strength is not sufficient or wrinkles are easily generated, and if the thickness is greater than 300 μm, there is a problem that the film becomes expensive. However, the thickness is not limited to 30 to 300 μm.

A material having transparency can be used as the flexible resin base material used for the lengthy plastic film 2. The light transmittance of the material is 80% or more, and 90% or more is more preferable. Since the material has transparency, positioning marks of single-board-like insulating substrates 4 having thin film semiconductor arrays 3 may be read and positioned to bond together.

An adhesive material that forms the adhesive material layer can be obtained by, for example, cross-linking acrylic copolymer obtained by copolymerizing low Tg monomer such as butyl acrylate, ethyl acrylate, 2-ethylhexyl acrylate, or the like which is used as a main monomer with functional group-containing monomer such as acrylic acid, methacrylic acid, hydroxyethyl methacrylate, hydroxyethyl acrylate, acrylamide, acrylic nitrile, or the like by using cross-linking agent such as isocyanate system, melamine system, epoxy system, or the like.

FIG. 3 is a diagram showing a schematic configuration of a flat panel display. The flat panel display according to the embodiment uses the thin film semiconductor substrate shown in FIG. 1. In the thin film semiconductor substrate, the single-board-like insulating substrates 4 are continuously bonded onto the lengthy plastic film 2, and the roll-shaped thin film semiconductor substrate including thin film semiconductor arrays 3 can be manufactured at low cost.

In the manufacturing process of the flat panel display, as shown in FIG. 3A, the lengthy protection film 6 is peeled, and as shown in FIG. 3B, the flat panel display is formed by combining the thin film semiconductor substrate with a plastic substrate 7 so that the thin film semiconductor substrate faces the plastic substrate 7.

The lengthy plastic film 2 of the thin film semiconductor substrate is a plastic film formed of the same material as that of the plastic substrate 7. Since the single-board-like insulating substrate 4 on which a thin film semiconductor array 3 is formed in advance is used, it is possible to use a lengthy plastic film 2 having an upper temperature limit lower than that of the manufacturing process of the semiconductor array 3. Since the plastic substrate 7 is a color filter, a flat panel display capable of color displaying can be formed. As described above, the roll-shaped thin film semiconductor substrate is faced to a plastic substrate 7 and can be quickly combined with the plastic substrate at an accurate position so as to be a flat panel display.

### [Apparatus for Manufacturing the Thin Film Semiconductor Substrate]

FIG. 4 is a schematic configuration diagram of an apparatus for manufacturing the thin film semiconductor substrate. The apparatus 1 according to the embodiment for manufacturing thin film semiconductor substrate is an apparatus for manufacturing the thin film semiconductor substrate which faces a plastic substrate and is combined with the plastic substrate so as to be a flat panel display. The apparatus 1 for manufacturing the thin film semiconductor substrate includes a rolling-out section 10, a bonding section 20, a peeling section 30, a laminating section 40, and a take-up section 50.

A rolling-out drum 11 around which the lengthy plastic film 2 is wound is disposed in the rolling-out section 10, and the lengthy plastic film 2 is sent out from the rolling-out drum 11. Positioning marks 60 for bonding are provided on the lengthy plastic film 2.

Image recognition apparatuses 21, a bonding roller 22, and a bonding table 23 are disposed in the bonding section 20. For example, a CCD camera is used in the image recognition apparatus 21. For example, a hard rubber roller or a resin roller is used for the bonding roller 22. For example, a table formed of a resin having a flat surface is used for the bonding table 23. By a drive from a supplying means 24, the single-board-like insulating substrate 4 including the thin film semiconductor array 3 is supplied, and positioning marks 61 for bonding are provided on the single-board-like insulating substrate 4.

The image recognition apparatuses 21 are disposed at positions for detecting the positioning marks 60 on the lengthy plastic film 2, reads the positioning marks 60 on the lengthy plastic film 2 and the positioning marks 61 on the single-board-like insulating substrate 4, controls the movement of the supplying means 24 so that the positioning marks 60 on the lengthy plastic film 2 match the positioning marks 61 on the single-board-like insulating substrate 4 in accordance with information of the read positioning marks 60 and 61, and performs positioning between the lengthy plastic film 2 and the single-board-like insulating substrate 4.

The bonding roller 22 presses the lengthy plastic film 2 to the single-board-like insulating substrate 4, and continuously bonds the single-board-like insulating substrates 4, onto which the protection film 5 for protecting the thin film semiconductor array 3 is bonded, onto the lengthy plastic film 2.

A peeling means 31 is disposed in the peeling section 30 in a position facing the protection film 5. The protection film 5 is heated or irradiated by ultraviolet light by the peeling means 31, and the protection film 5 is peeled from the single-board-like insulating substrates 4.

A rolling-out drum 41 around which the lengthy protection film 6 is wound is disposed in the laminating section 40, and the lengthy protection film 6 is sent out from the rolling-out drum 41. By using a laminating roller 42, the lengthy protection film 6 is laminated to the lengthy plastic film 2 so as to protect the thin film semiconductor array 3.

A take-up drum 51 is disposed in the take-up section 50, and the lengthy plastic film 2 to which the lengthy protection film 6 is laminated is taken up in a roll-shape by the take-up drum 51.

As described above, the manufacturing process of the thin film semiconductor substrate includes a process for forming the thin film semiconductor substrate by continuously bonding a plurality of single-board-like insulating substrates 4 including the thin film semiconductor array 3 onto the lengthy plastic film 2, and a process for taking up the thin film semiconductor substrate in a roll shape. Thus, the roll-shaped thin film semiconductor substrate including the thin film semiconductor arrays 3 can be manufactured at low cost, and the thin film semiconductor substrate can be easily stored and transported.

In addition, since the single-board-like insulating substrate 4 on which the thin film semiconductor array 3 is formed in advance is used, it is possible to use the lengthy plastic film 2 having an upper temperature limit lower than that of the manufacturing process of the semiconductor array 3, and also it is possible to obtain the thin film semiconductor substrate which can be taken up in a roll-shape by continuously bonding the single-board-like insulating substrates 4 onto the lengthy plastic film 2.

The present invention can be applied to a thin film semiconductor substrate formed by continuously bonding single-board-like insulating substrates including a thin film semiconductor array onto a lengthy plastic film and an apparatus for manufacturing the same. According to the present invention, mass production of flat panel displays is possible, and the thin film semiconductor substrate can be easily stored and transported at low cost without needing a special storage container or storage space.

### BRIEF DESCRIPTION OF THE DRAWINGS

FIG. 1 is a schematic configuration diagram of a thin film semiconductor substrate;

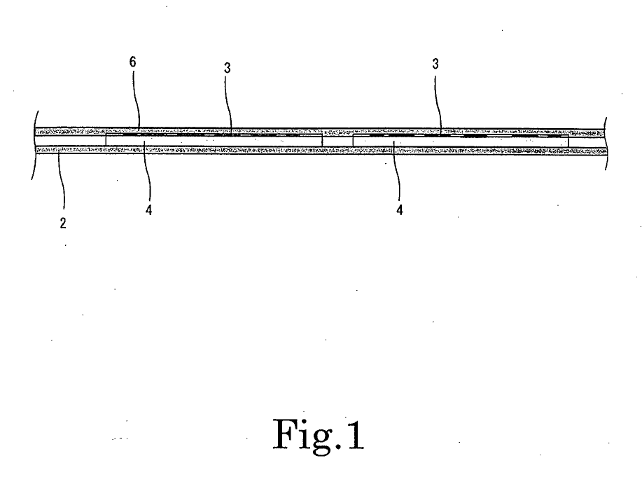

FIG. 2 is a diagram for explaining a manufacturing process of the thin film semiconductor substrate;

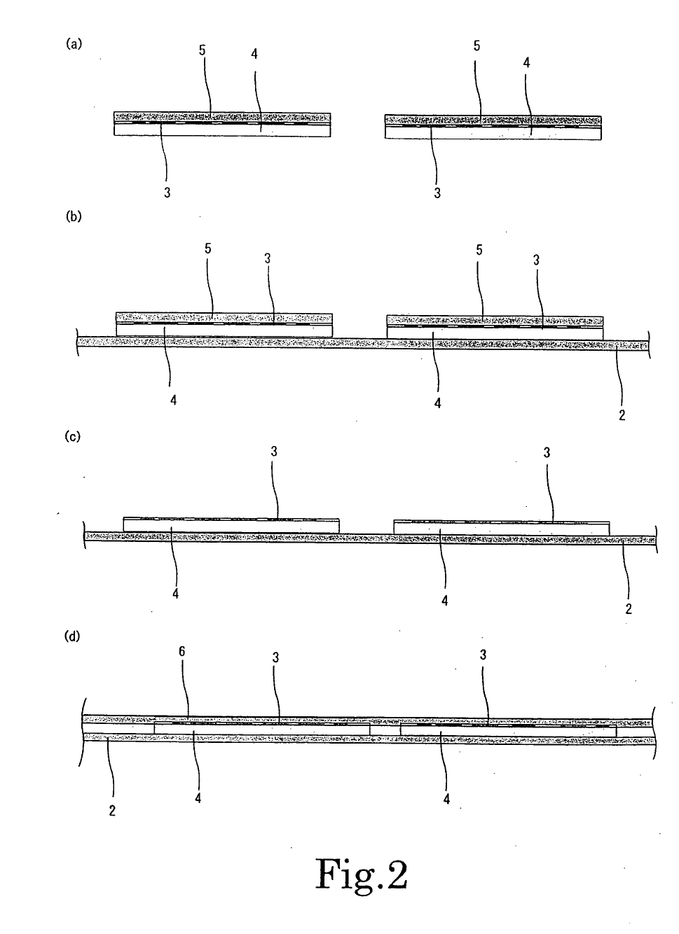

FIG. 3 is a diagram showing .a schematic configuration of a flat panel display; and

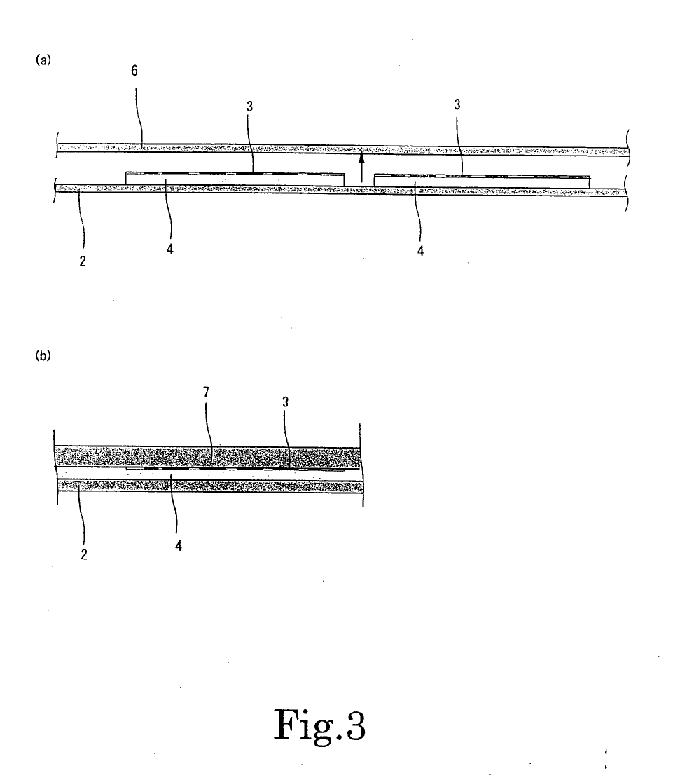

FIG. 4 is a schematic configuration diagram of an apparatus for manufacturing a thin film semiconductor substrate.

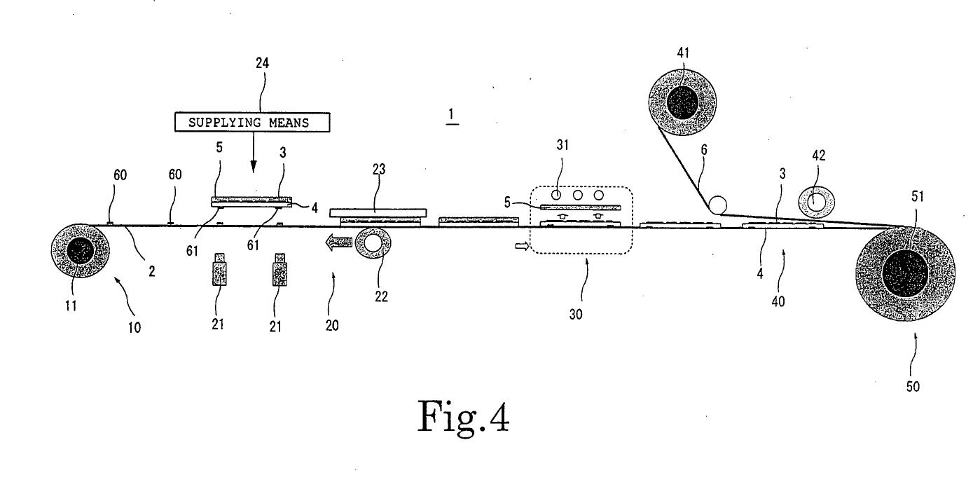

### DESCRIPTION OF REFERENCE NUMERALS

1 Apparatus for manufacturing a thin film semiconductor substrate
2 Lengthy plastic film
3 Thin film semiconductor array
4 Single-board-like insulating substrate
5 Protection film
6 Lengthy protection film
7 Plastic substrate of flat panel display
10 Rolling-out section
20 Bonding section
30 Peeling section
40 Laminating section
50 Take-up section

1. A thin film semiconductor substrate that faces a plastic substrate and is combined with the plastic substrate so as to be a flat panel display,
wherein single-board-like insulating substrates each of which has a thin film semiconductor array are continuously bonded onto a lengthy plastic film.

2. The thin film semiconductor substrate according to claim 1, wherein the insulating substrates are formed by laminating a lengthy protection film to the insulating substrates so that the insulating substrates are protected by the lengthy plastic film.

3. The thin film semiconductor substrate described in claim 1, wherein the lengthy plastic film is formed of the same material as that of the plastic substrate.

4. The thin film semiconductor substrate according to claim 1, wherein the thickness of the thin film semiconductor array is 0.1 mm or less.

5. The thin film semiconductor substrate according to claim 1, wherein the plastic substrate is a color filter.

6. An apparatus for manufacturing a thin film semiconductor substrate which faces a plastic substrate and is combined with the plastic substrate so as to be the flat panel display, the apparatus comprising:
a bonding section for continuously bonding, onto the lengthy plastic film, the single-board-like insulating substrates each of which has a protection film bonded thereon for protecting the thin film semiconductor array,
a peeling section for peeling the protection film by heating or ultraviolet irradiation,
a laminating section which laminates a lengthy protection film on the lengthy plastic film so as to protect the thin film semiconductor array, and
a take-up section for taking up, in a roll-shape, the lengthy plastic film, which has the lengthy protection film laminated thereon.

7. The apparatus according to claim 6 for manufacturing a thin film semiconductor substrate, wherein the lengthy plastic film is formed of the same material as that of the plastic substrate.

8. The apparatus according to claim 6 for manufacturing a thin film semiconductor substrate, wherein the thickness of the thin film semiconductor array is 0.1 mm or less.
